(19) United States
(12) Patent Application Publication
(10) Pub. No.: US 2015/0004721 A1
(43) Pub. Date: Jan. 1, 2015

(54) PLASMA PROCESSING APPARATUS AND PLASMA PROCESSING METHOD

(71) Applicant: TOKYO ELECTRON LIMITED, Tokyo (JP)

(72) Inventors: Toshikazu Akimoto, Tokyo (JP); Hiroshi Kannan, Tokyo (JP)

(73) Assignee: TOKYO ELECTRON LIMITED, Tokyo (JP)

(21) Appl. No.: 14/375,872

(22) PCT Filed: Jan. 30, 2013
(86) PCT No.: PCT/JP2013/000487

§ 371 Date: Jul. 31, 2014

(30) Foreign Application Priority Data
Feb. 3, 2012 (JP) 2012-021991

(51) Int. Cl. H01L 21/67; H01L 21/66; H01L 21/3065; H01J 37/32

(52) U.S. Cl. CPC H01L 21/67069; H01J 37/32972; H01L 22/10; H01L 22/20; H01L 21/3065
USPC 438/9; 156/345.24; 216/60

(57) ABSTRACT

An OES measuring unit outputs a spectroscopically measured value for each step at the end of or immediately after each step. A CD estimating unit obtains an estimated CD value for each step using a CD estimation model and a spectroscopically measured value received from an estimation model storage unit. In the next step, a process control unit uses an estimated CD value for the previous step received from the CD estimating unit, in addition to a process condition setting value for the next step received from a recipe storage unit and a process control model for the next step received from a control model storage unit, for automatic control of the control subject

### TECHNICAL FIELD

The present disclosure relates to a plasma processing apparatus and a plasma processing method using an advanced process control (APC).

### BACKGROUND

In a plasma processing apparatus currently used in manufacturing semiconductor devices or flat panel displays (FPDs), a process window has become gradually narrower as devices have been miniaturized and substrates have been enlarged. On the other hand, it is requested for further enhancement of the productivity and the device performance.

In this background, a process control method has been gradually introduced into a plasma processing apparatus so as to ensure that the same process results may be obtained each time when the same process is repeated, that is, there is no fluctuation or unevenness. The unevenness of interest in such a plasma control includes, in terms of causes, a machine error between a drift of a process condition and an apparatus or a chamber, and, in terms of phenomena, unevenness between lots, unevenness in a lot, and furthermore, unevenness before or after cleaning or seasoning.

As a measure to suppress the unevenness, there was initially adopted a method of performing a process by setting a proportion (correction amount) of sequentially correcting a specific process condition per lot unit or wafer unit in advance to a recipe that instructs a process condition and an order for a given single-wafer plasma processing, and referring the recipe table. However, since this method sets the correction amount included in the recipe table as a fixed value, adaptability and accuracy to various disturbances are insufficient, and thus, it is difficult to precisely control uneven plasma processes.

Accordingly, plasma processing apparatuses employing an APC technique have recently increased in which process variations are suppressed by a feedback control or a feedforward control. In particular, a width of a gate electrode, which is the most important parameter affecting characteristics of MOS transistors, is called a gate CD (critical dimension CD), and the APC is gradually increasingly incorporated in plasma processing apparatuses for gate etching, mounting in order to suppress unevenness of the gate CDs.

A conventional APC used in the plasma processing apparatus monitors a status of the apparatus during processing in one single-wafer plasma processing using an in-situ sensor, and estimates a process result (e.g., a CD value) based on the measured value of the in-situ sensor using a processed result estimating model after finishing the processing. Then, according to a deviation between an estimated value of the process result and a target value, a value of the process condition is corrected so as to bring the deviation close to zero in the next single-wafer plasma processing (see, e.g., Patent Document 1). Alternatively, there has been suggested a method in which an optimal recipe calculation model for operating a value of the optimal process condition for the target value of the process result is provided to revise the optimal recipe calculation model according to the deviation, instead of correcting the value of the process condition (see, e.g., Patent Document 2).

### PRIOR ART DOCUMENT

### Patent Document

Patent Document 1: Japanese Laid-Open Patent Publication No. 2003-17471

Patent Document 2: Japanese Laid-Open Patent Publication No. 2004-119753

### DISCLOSURE OF THE INVENTION

### Problems to be Solved

As described above, the conventional APC in the plasma processing apparatus is a so-called run-to-run type apparatus of performing a feedback control or a feedforward control in a single-wafer plasma processing unit, that is, a wafer unit, but is not a real-time type apparatus of performing a feedback control or a feedforward control when one single-wafer plasma processing is performed on one sheet of wafer. Therefore, it is not possible to be adopted in an application in which process conditions or recipes are switched during one single-wafer plasma processing. Accordingly, it is not possible to precisely suppress fluctuation or unevenness of the CD, for example, in a multilayer resist method in which a multilayered film is subjected to an etching processing successively in a plurality of steps.

The present disclosure has been made in consideration of the problems in the related art, and provides a plasma processing apparatus and a plasma processing method capable of precisely suppressing fluctuation or unevenness of a plasma process by an APC functioning during one single-wafer plasma processing.

Specifically, the present disclosure provides a plasma processing apparatus and a plasma processing method having an APC function which is suitably applicable to a multi-step type apparatus of dividing one single-wafer plasma processing into a plurality of steps with different recipes.

### Means to Solve the Problems

According to a first aspect, the present disclosure provides a plasma processing apparatus in which a plasma processing for a substrate to be processed is divided into a plurality of steps and process conditions are independently set at each step. The apparatus includes: an evacuable processing container configured to removably accommodate the substrate; a plasma generating unit configured to generate plasma of a processing gas in the processing container in accordance with the process conditions for each step; a target value setting unit configured to set a target value for each step on a determined process result; a plasma measuring unit configured to spectroscopically measure atomic emission of the plasma generated in the processing container; a process result estimating unit configured to estimate a value of the process result in a corresponding step from a spectroscopically measured value obtained from the plasma measuring unit after the completion of each step; and a process control unit configured to adjust at least one of the process conditions as a process parameter in a next step of each step, based on the target value of the process result for the next step given from the target value setting unit and an estimated value of the process result for each step given from the process result estimating unit.

According to the first aspect, the present disclosure provides a plasma processing method in which a plasma processing for a substrate to be processed is divided into a plurality of steps and process conditions are independently set for each step. The method includes: setting a target value for each step on a determined process result; generating plasma of a processing gas in an evacuable processing container configured to removably accommodate the substrate; spectroscopically measuring atomic emission of the plasma generated in the processing container to determine a spectroscopically measured value; estimating a value of the process result in a corresponding step from the spectroscopically measured value after the completion of each step; and adjusting at least one of the process conditions as a process parameter in the next step of each step, based on the target value of the process result for the next step and the estimated value of the process result for each step.

In the first aspect, since setting of a target value of a process result, spectroscopic measurement of a plasma atomic emission, estimation of the value of the process result, and adjustment of a process parameter are all performed in a step unit, an APC may be established which can perform a control between steps during one single-wafer plasma processing.

According to the first aspect, the present disclosure provides a plasma processing apparatus in which a plasma processing for a substrate to be processed is divided into a plurality of steps and process conditions are independently set for each step. The apparatus includes: an evacuable processing container configured to removably accommodate the substrate; a process condition setting unit configured to set process conditions for performing a plasma processing on one substrate to be processed; a plasma generating unit configured to generate plasma of a processing gas in the processing container in accordance with the process conditions; a target value setting unit configured to set a target value on a determined process result; a plasma measuring unit configured to spectroscopically measure atomic emission of the plasma generated in the processing container and calculate a spectroscopically measured value in a predetermined interval of time; a process result predicting unit configured to predict a value of the process result from the spectroscopically measured value obtained from the plasma measuring unit in a predetermined interval of time; and a process control unit configured to adjust at least one of the process conditions in a corresponding step as a process parameter, based on the target value of the process result given from the target value setting unit and the predicted value of the process result for each step given from the process estimating unit in a predetermined interval of time.

In the second aspect, since setting of a target value of a process result, spectroscopic measurement of a plasma atomic emission, prediction of a value of the process result, and adjustment of a process parameter are all performed in a predetermined interval of time, an APC may be established which can perform a real-time control.

In the present disclosure, the term, “real-time control” does not refer to a high-speed processing system, but refer to a control requiring a constraint condition about time, which produces a result in accordance with a determined time. Here, the term, “determined time” refers to a lot unit, a wafer unit, a recipe unit, a step unit in a recipe, a second unit, or a millisecond unit.

### Effect of the Invention

According to the plasma processing apparatus or the plasma processing method of the present disclosure, the configuration and action as described above may precisely suppress fluctuation or unevenness of a plasma process by an APC functioning during one single-wafer plasma processing, and in particular, bring a great advantage in a multi-step type apparatus.

### BRIEF DESCRIPTION OF THE DRAWINGS

FIG. 1 is a view illustrating a layout of a cluster tool type vacuum processing apparatus to which the plasma processing apparatus of the present disclosure is applicable.

FIG. 2 is a view illustrating a configuration of a microwave plasma processing apparatus which may be mounted, as a process module, in the cluster tool type vacuum processing apparatus of FIG. 1.

FIG. 3 is a view illustrating an exemplary multilayer resist method which may be performed in the microwave plasma processing apparatus.

FIG. 4 is a view illustrating an exemplary recipe used in an etching processing of the multilayer resist method.

FIG. 5 is a view illustrating an exemplary etching processing of the multilayer resister method in which a target value of a CD is set at each step.

FIG. 6 is a block diagram illustrating an exemplary embodiment of an APC mechanism mounted in the microwave plasma processing apparatus.

FIG. 7 is a flow chart illustrating a main processing procedure of the APC mechanism of FIG. 6.

FIG. 8 is a view illustrating a structure of switching a plasma condition setting value, a target CD value, a process control model and an estimated CD value at each step in a table.

FIG. 9A is a view illustrating a correlation (a first function) between a process parameter and a measured CD value.

FIG. 9B is a view illustrating a correlation (a second function) between a process parameter and a spectroscopically measured value.

FIG. 9C is a view illustrating a correlation (a third function) between a spectroscopically measured value and a measured CD value.

FIG. 10 is a flow chart illustrating a sequence of establishing a CD estimation model of the exemplary embodiment by a PLSR method.

FIG. 11 is a view illustrating a three-dimensional spectrum of OES data (spectroscopically measured value) obtained from an OES measuring unit.

FIG. 12 is a view illustrating a spectrum of an OES at a time point.

FIG. 13 is a diagram in which a change in spectrum at a wavelength on a time axis is plotted.

FIG. 14 is a flow chart illustrating a sequence of an on-line signal processing to obtain an estimated CD value using a CD estimation model of PLSR.

FIG. 15 is a diagram in which an estimated CD value and a measured CD value are plotted.

FIG. 16 is a scatter diagram in which the data of FIG. 15 are plotted.

FIG. 17 is a block diagram illustrating another exemplary embodiment of the APC mechanism mounted in the microwave plasma processing apparatus.

FIG. 18 is a flow chart illustrating a main processing procedure of the APC mechanism of FIG. 17.

### DETAILED DESCRIPTION TO EXECUTE THE INVENTION

Hereinafter, preferred exemplary embodiments of the present disclosure will be described with reference to the accompanying drawings.

[Multi-Chamber System in Exemplary Embodiment]

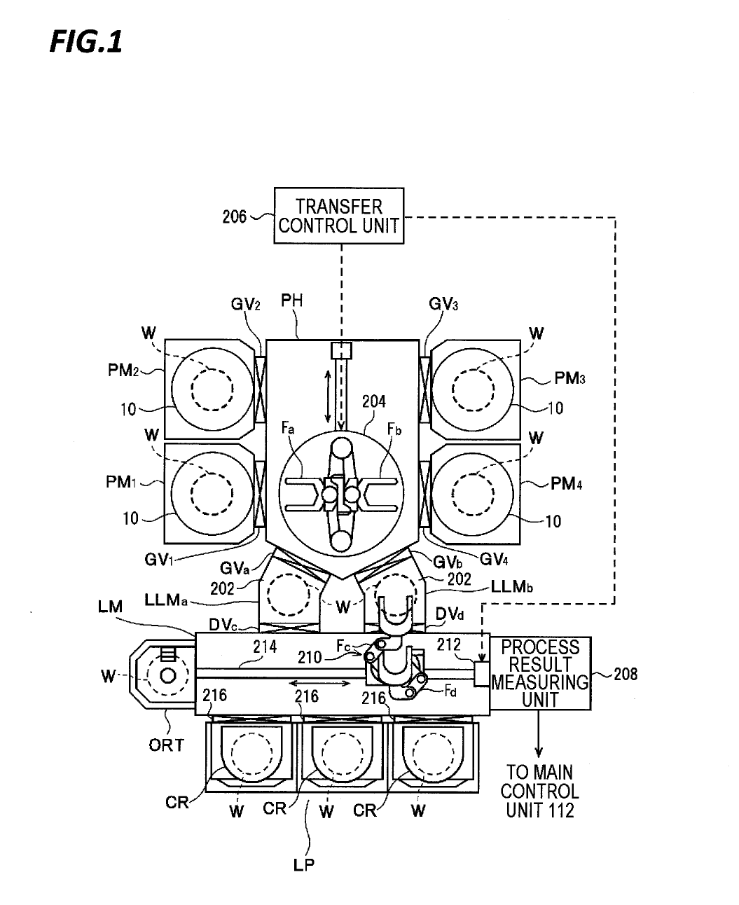

FIG. 1 is a view illustrating an exemplified configuration of a cluster tool type vacuum processing apparatus to which the plasma processing apparatus of the present disclosure is applicable. The vacuum processing apparatus is installed in a clean room, and provided with, for example, four process modules PM₁, PM₂, PM₃, PM₄ and two load lock modules LLMₐ, LLM_{b} which are arranged in a cluster form around a substantially pentagonal platform or vacuum transfer chamber PH extending in an apparatus depth direction.

More specifically, the vacuum transfer chamber PH is connected with two process modules PM₁, PM₂ through gate valves GV₁, GV₂, respectively, at a longer side on the left portion of the figure, connected with two process modules PM₃, PM₄ through gate valves GV₃, GV₄, respectively, at another longer side on the right portion of the figure, and connected with load lock modules LLMₐ, LLM_{b} through gate valves GVₐ, GV_{b}, respectively, at a pair of shorter sides extending in a V shape on the lower portion of the figure.

Each of the process modules PM₁, PM₂, PM₃, PM₄ is provided with a vacuum chamber 10 the inside of which is constantly maintained in a decompressed state at a variable pressure by each dedicated exhaust device (not illustrated), and typically configured to perform a desired single-wafer plasma processing, for example, a vacuum film forming processing such as a dry etching processing, chemical vapor deposition (CVD), atomic layer deposition (ALD) or sputtering, heat treatment, ashing, and a cleaning processing of semiconductor wafer surfaces by placing a single substrate to be processed, for example, a semiconductor wafer W on a placing table or susceptor (not illustrated) disposed in a central portion in the vacuum chamber 10 and using a predetermined power (e.g., processing gas, electric power and decompression).

Each of the load lock modules LLMₐ, LLM_{b} is configured to communicate with a standby transfer chamber of a loader transfer chamber LM (to be described later) through door valves DV_{c}, DV_{d}, respectively, and provided with a placing table or delivery table (not illustrated) to temporarily hold a semiconductor wafer W transferred between the loader transfer chamber LM and the vacuum transfer chamber PH, in each load lock chamber 202.

The vacuum transfer chamber PH is connected to a dedicated evacuation device (not illustrated), and the inside thereof is normally maintained in a decompression state at a constant pressure. In the vacuum transfer chamber PH, a single-wafer vacuum transfer robot (substrate transfer device) 204 provided with a pair of stretchable transfer arms Fₐ, F_{b} is installed to be slidable, pivotable and elevatable. The vacuum transfer robot 204 is configured to move back and forth between the process modules PM₁ to PM₄ and the load lock modules LLMₐ, LLM_{b} in response to commands from a transfer control unit 206 to transfer semiconductor wafers W one by one.

A load port LP, an alignment mechanism ORT, and a process result measuring unit 208 are provided adjacent to the loader transfer chamber LM. The load port LP is used to introduce or withdraw a wafer cassette CR in which the wafer cassette CR may accommodate, for example, 25 sheets of semiconductor wafers W of one batch, into or from an external transfer vehicle. Here, each wafer cassette CR is configured as a front open unified pod (FOUP) or a standard mechanical interface (SMIF) box. The alignment mechanism ORT is used to align notches or orientation flats of the semiconductor wafers W with a predetermined position or direction. The process result measuring unit 208 measures predetermined process results (e.g., a CD value, shape, film thickness, and composition) with respect to the processed semiconductor wafers W which has been subjected to a plasma processing in any one of the process modules PM₁ to PM₄ and returned to the loader transfer chamber LM, or the processed semiconductor wafers W which has been sampled periodically. For example, in a case of measuring a CD value as a process result, an integrated metrology (IM) device may be preferably used.

A single-wafer standby transfer robot (substrate transfer device) 210 installed in the loader transfer chamber LM is provided with a pair of stretchable transfer arms F_{c}, F_{d}, and configured to be movable horizontally on a linear guide 214 of a linear motor 212, pivotable and elevatable, and to move back and forth between the load port LP, the orientation flat alignment mechanism ORT, the load lock modules LLMₐ, LLM_{b}, and the process result measuring unit 208 in response to commands from the transfer control unit 206 to transfer the semiconductor wafers W one by one.

Here, descriptions will be made on a basic wafer transfer sequence in which one sheet of the wafer in the wafer cassette CR introduced to the load port LP is subjected to a series of processings in the cluster tool.

The standby transfer robot 210 in the loader transfer chamber LM takes out one sheet of the semiconductor wafer W from the wafer cassette CR on the load port LP in a state where an LP door 216 is opened, transfers the semiconductor wafer W to the alignment mechanism ORT to be subjected alignment, and transports the aligned semiconductor wafer W to any one (e.g., LLMₐ) of the load lock modules LLMₐ, LLM_{b}. The load lock module LLMₐ serving as a transport destination receives the semiconductor wafer W in an atmospheric state, evacuates the inside after carry-in, and delivers the semiconductor wafer W to the vacuum transfer robot 204 of the vacuum transfer chamber PH in a decompression state.

The vacuum transfer robot 204 carries the semiconductor wafer W taken out from the load lock module LLMₐ to a first process module (e.g., PM₁) using any one of the transfer arms Fₐ, F_{b}. In the process module PM₁, a single-wafer processing of a first step is performed under predetermined process conditions (e.g., gas, pressure, electric power, and time) in accordance with a recipe set in advance.

After the single-wafer processing of the first step is completed, the vacuum transfer robot 204 carries the semiconductor wafer W out of the process module PM₁, and then, carries the semiconductor wafer W into a second process module (e.g., PM₂) when there is a next step, or transfers the semiconductor wafer W to one of the load lock modules LLMₐ, LLM_{b} when there is no next step. When the wafer is carried into the second process module (e.g., PM₂), in the process module PM₂, a single-wafer processing of a second step is also performed under predetermined process conditions in accordance with a recipe set in advance.

After the single-wafer processing of the second step is completed, the vacuum transfer robot 204 carries the semiconductor wafer W out of the second process module PM₂, and then, carries the semiconductor wafer W into a third process module (e.g., PM₃) when there is a next step, or transfers the semiconductor wafer W to one of the load lock modules LLMₐ, LLM_{b} when there is no next step. Even in a case where a processing is performed in the third module (e.g., PM₃), the vacuum transfer robot 204 also carries the semiconductor wafer W into a process module (e.g., PM₄) in a subsequent step when there is a next step thereafter, or returns the semiconductor wafer W to one of the load lock modules LLMₐ, LLM_{b} when there is no next step.

As described above, when the semiconductor wafer W subjected to one single-wafer plasma processing or a series of single-wafer plasma processings in the process modules PM₁, PM₂, . . . under vacuum is carried into one of the load lock module (e.g., LLM_{b}) in the above-described manner, the inside of the load lock module LLM_{b} is converted from the decompression state to an atmospheric state. Thereafter, the standby transfer robot 210 in the loader transfer chamber LM takes out the semiconductor wafer W from the load lock module LLM_{b} in the atmospheric state, and carries the processed semiconductor wafer W into the process result measuring unit 208.

Then, when the process result measuring unit 208 finishes the measurement or evaluation of process results with respect to the semiconductor wafer W, the standby transfer robot 210 takes out the semiconductor wafer W from the process result measuring unit 208, and returns the taken semiconductor wafer W to the corresponding wafer cassette CR.

In the cluster tool type vacuum processing apparatus, as one system type, the plasma processing apparatuses of the same model are used for all four process modules PM₁ to PM₄ so as to allow the plasma processing apparatuses PM₁ to PM₄ to perform a plasma processing with the same recipes. In that case, when the single-wafer processing of the first step is completed in each of the process modules PM₁ to PM₄, the vacuum transfer robot 204 transfers the processed semiconductor wafer carried out from the corresponding process module directly to any one of the load lock module LLMₐ, LLM_{b} because there is no next step, that is, the second step. Although not illustrated, the vacuum processing apparatus is provided with a system controller for an integrated control of operations of the whole system.

[Plasma Processing Apparatus in Exemplary Embodiment]

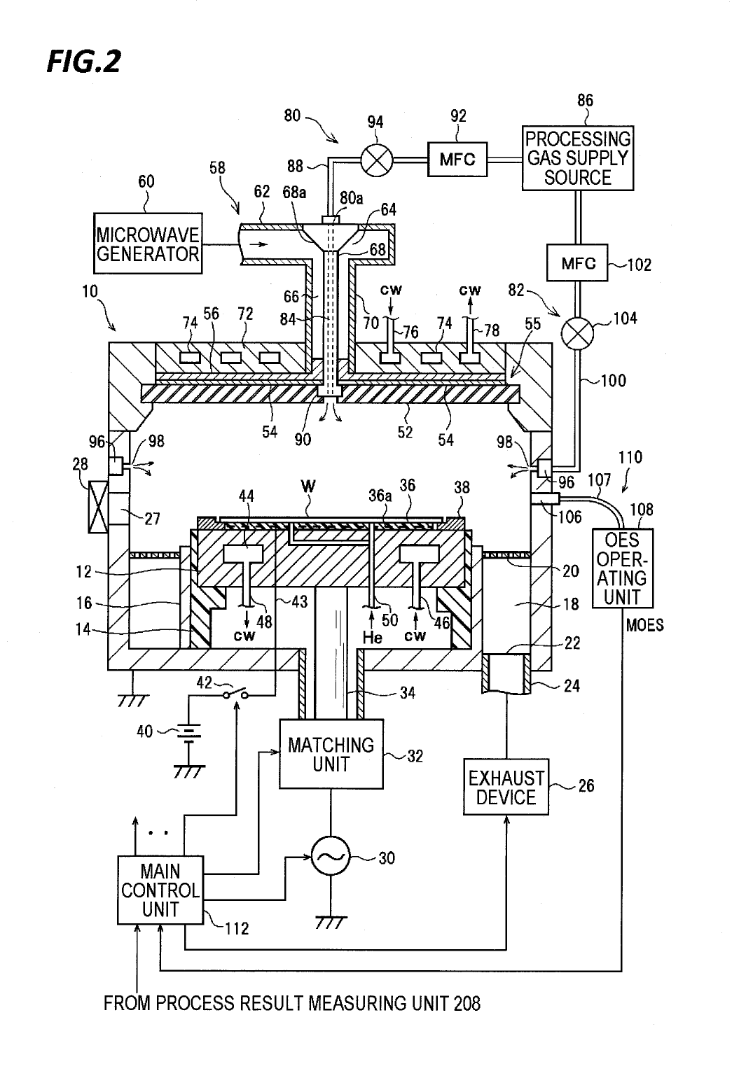

FIG. 2 illustrates a configuration of a microwave plasma processing apparatus according to an exemplary embodiment of the present disclosure which can be mounted as one of the process modules PM₁ to PM₄ to the cluster tool type vacuum processing apparatus. The microwave plasma processing apparatus performs a plasma processing such as, for example, plasma etching, plasma CVD, and plasma ALD under surface wave plasma excited using microwaves and a flat plate slot antenna, and is provided with a cylindrical vacuum chamber (processing container) 10 made of metal such as aluminum or stainless steel. The chamber 10 is grounded.

First, descriptions will be made on respective elements which are not involved in producing plasma in the microwave plasma processing apparatus.

At the lower center in the chamber 10, a disc-shaped susceptor 12 configured to place, for example, a semiconductor wafer W as a substrate to be processed, is disposed as a substrate holding table horizontally. The susceptor 12 is supported by a cylindrical insulating support portion 14 which is made of, for example, aluminum and extends vertically upwards from the bottom of the chamber 10.

An annular exhaust path 18 is formed along the outer periphery of the cylindrical support portion 14 between the inner wall of the chamber 10 and a cylindrical conductive support portion 16 which extends vertically upwards form the bottom of the chamber 10. An annular baffle plate 20 is attached to the upper portion or inlet of the exhaust path 18, and one or more exhaust ports 22 are provided in the bottom portion. Each exhaust port 22 is connected with an exhaust device 26 through an exhaust pipe 24. The exhaust device 26 is provided with a vacuum pup such as a turbo-molecular pump, and thus, may decompress the plasma processing space in the chamber 10 to a desired degree of vacuum. Outside the sidewall of the chamber 10, a gate valve 28 is provided to open/close a carry-in/out port 27 of the semiconductor wafer W.

An electrostatic chuck 36 is installed On the top of the susceptor 12, in which the electrostatic chuck 36 is be provided with a bias electrode configured to draw ions to the semiconductor wafer W and an electrode 36a configured to hold the semiconductor wafer W by an electrostatic attraction force. The bias electrode is electrically connected with a high frequency power source 30 for RF bias through a matching unit 32 and a power feeding rod 34. The high frequency power source 30 outputs a predetermined power having a certain frequency suitable to control energy of the ions drawn to the semiconductor wafer W, for example, a high frequency of 13.56 MHz. The matching unit 32 accommodates a matcher which takes matching between impedance of the high-frequency power source 30 and impedance of loads (mainly electrodes, plasma and chamber). A blocking condenser is included in the matcher.

A focus ring 38 is installed at a radially outside of the electrostatic chuck 36 to surround the periphery of the semiconductor wafer W in an annular form. The electrode 36a is electrically connected with a high-voltage DC power source 40 through a switch 42 and a coated wire 43. The semiconductor wafer W may be attracted to and held on the electrostatic chuck 36 with the electrostatic force by DC voltage applied from the DC power source 40.

An annular coolant flow path 44 is formed inside the susceptor 12 to extend, for example, circumferentially. A coolant at a predetermined temperature, for example, a fluorine-based heat medium or cooling water cw is circulated and supplied from a chiller unit (not illustrated) through pipes 46, 48 to the coolant flow path 44. The processing temperature of the semiconductor wafer W on the electrostatic chuck 36 may be controlled by the temperature of the coolant. Further, a heat transfer gas from a heat transfer gas supplying unit (not illustrated), for example, helium (He) gas, is supplied through a gas supplying pipe 50 to a gap between the upper surface of the electrostatic chuck 36 and the rear surface of the semiconductor wafer W. Further, lift pins and an elevation mechanism thereof (not illustrated) may also be provided to be movable up and down vertically through the susceptor 12 so as to load/unload the semiconductor wafer W.

Next, descriptions will be made on respective elements which are involved in producing plasma in the microwave plasma etching apparatus.

A circular dielectric window 52 configured to introduce microwaves is hermetically attached as a top plate to the ceiling facing the susceptor 12 of the chamber 10. The space in the chamber just below the dielectric window 52 is the plasma producing space. The dielectric window 52 is made of a dielectric that transmits microwaves, for example, ceramic such as quartz or Al₂O₃.

The dielectric window 52 is provided with a conductor slot plate 54 attached or disposed on the top surface thereof. The slot plate 54 is provided with a plurality of rotationally symmetric slot pairs (not illustrated) that are distributed concentrically, as slots to emit microwave. Above the slot plate 54, a dielectric plate 56 is provided to shorten the wavelength of the microwaves that propagate inside. The slot plate 54 is electromagnetically coupled to a microwave transmission line 58. A flat plate slot antenna, for example, a disc-shaped radial line slot antenna 55 is configured with an antenna rear surface plate installed on the slot plate 54, the dielectric plate 56, and a facing surface of the slot plate.

The microwave transmission line 58 transmits microwaves of, for example, 2.45 GHz, which are output from a microwave generator 60, to the radial line slot antenna 55. The microwave transmission line 58 includes a waveguide tube 62, a waveguide tube-coaxial tube converter 64, and a coaxial tube 66. The waveguide tube 62 is, for example, a rectangular waveguide tube, and transmits the microwaves from the microwave generator 60 to the waveguide tube-coaxial tube converter 64 using a TE mode as a transmission mode.

The waveguide tube-coaxial tube converter 64 combines a terminating end of the rectangular waveguide tube 62 with a starting end of the coaxial tube 66 to convert the transmission mode of the rectangular waveguide tube 62 to the transmission mode of the coaxial tube 66. The coaxial tube 66 extends vertically downwards from the waveguide tube-coaxial tube converter 64 to the central portion of the upper surface of the chamber 10, and the terminating end of the coaxial line thereof is coupled to the radial line slot antenna 55 through the dielectric plate 56. An external conductor 70 of the coaxial tube 66 includes a cylindrical body formed integrally with the rectangular waveguide tube 62, and the microwaves are propagated in the TEM mode to the space between an internal conductor 68 and the external conductor 70.

The microwaves output from the microwave generator 60 are propagated in the waveguide tube 62, the waveguide tube-coaxial tube converter 64, and the coaxial tube 66 of the microwave transmission line 58 as described above, and fed to the radial line slot antenna 55 through the dielectric plate 56. And, the microwaves spread in the radial direction in the dielectric plate 56 while shortening the wavelength are radiated as plane waves of circular polarized waves including two polarized components orthogonal to each other, from each slot pairs of the antenna 55 to the inside of the chamber 10. And, gas near the dielectric window 52 is ionized by the electric field (microwave electric field) of the surface waves propagated in the radial direction along the surface of the dielectric window 52 so that plasma having a low electron temperature may be generated at a high density.

A cooling jacket plate 72 also serving as an antenna rear surface plate is installed on the dielectric plate 56 so as to cover the upper surface of the chamber 10. The cooling jacket plate 72 is made of, for example, aluminum, and has a function to absorb (radiate) heat generated from the dielectric window 52 and the dielectric plate 56. For the cooling function, a coolant at a predetermined temperature, for example, a fluorine-based heat medium or cooling water cw is circulated and supplied from a chiller unit (not illustrated) to a flow path 74 formed in the cooling jacket plate 72 through pipes 76, 78.

The microwave plasma processing apparatus includes, as a gas introduction mechanism configured to introduce a processing gas into the chamber 10, two routes of an upper gas introducing unit 80 including a gas flow path formed in the dielectric window 52 and a lateral (side) gas introducing unit 82 including a gas flow path formed in the sidewall of the chamber 10.

The upper gas introducing unit 80 is formed with a hollow gas flow path 84 penetrating through the internal conductor 68 of the coaxial tube 66 in the axial direction. An upper end of the internal conductor 68 is connected with a first gas supplying pipe 88 from a processing gas supply source 86, and a gas flow path of the first gas supplying pipe 88 is communicated with the gas flow path 84 of the coaxial tube 66.

A lower end of the internal conductor 68 is connected with a gas nozzle or an injector 90. The gas flow path 84 of the coaxial tube 66 is communicated with a gas flow path of the injector 90. The injector 90 is inserted into a through-hole of the dielectric window 52, and a tip end (discharge port) thereof faces the plasma producing space in the chamber 10.

In the upper processing gas introducing unit 82 having such a configuration, the processing gas sent at a predetermined pressure from the processing gas supply source 86 flows through the respective gas flow paths of the first gas supplying pipe 88 and the coaxial tube 66 sequentially, and is injected from the discharge port of the injector 90 so as to be diffused to the plasma producing space in the chamber 10. Meanwhile, a mass flow controller (MFC) 92 and an opening/closing valve 94 are provided in the middle of the first gas supplying pipe 88.

The lateral gas introducing unit 82 includes: a buffer room (manifold) 96 which is located at a position lower than the bottom surface of the dielectric window 52 and formed in the sidewall (or at the inner side) of the chamber 10 in an annular form; a plurality of sidewall gas injection ports 98 which faces the plasma producing space from the buffer room 96 at equal intervals in the circumferential direction; and a second gas supplying pipe 100 which extends from the processing gas supply source 86 to the buffer room 96. An MFC 102 and an opening/closing valve 104 are provided in the middle of the second gas supplying pipe 100.

In the lateral gas introducing unit 82, the processing gas (e.g., an etching gas or a film forming gas) sent at a predetermined pressure from the processing gas supply source 86 is introduced into the buffer room 96 in the sidewall of the chamber 10 through the second gas supplying pipe 100, and is injected substantially horizontally from the respective sidewall gas injection ports 98 after the pressure in the circumferential direction is equalized in the chamber 10, so as to be diffused to the plasma producing space from the peripheral portion in the chamber 10 towards the central portion.

Meanwhile, the processing gases introduced from the upper gas introducing unit 80 and the lateral gas introducing unit 82, respectively, into the chamber 10 may be the same as or different from each other, and each may be introduced at an independent flow rate through the MFCs 92, 102, or at any flow rate.

On the sidewall of the chamber 10, an optical sensor 106 is attached at a position slightly higher than the upper surface of the susceptor 12 to monitor atomic emission of the plasma. An output of the optical sensor 106 is connected to an optical emission spectroscopy (OES) operating unit 108 through an optical fiber 107. The optical sensor 106, the optical fiber 107, and the OES operating unit 108 constitute an OES measuring unit 110. The OES measuring unit 110 spectroscopically measures atomic emission of the plasma, which is an observable quantity of state produced in the chamber 10, and acquires a predetermined spectroscopically measured value (MOES) in terms of its intensity for a specific spectrum or all spectra within a certain range.

A main control unit 112 is provided with one or more microcomputers so as to control individual operations of the respective units in the microwave plasma processing apparatus, for example, the exhaust device 26, the high-frequency power source 30, the switch 42 for the electrostatic chuck 36, the microwave generator 60, the upper gas introducing unit 80, the lateral gas introducing unit 82, the processing gas supply source 86, and a heat transfer gas supplying unit (not illustrated), and operations of the entire apparatus. Further, the main control unit 112 is configured to accept the spectroscopically measured value (MOES) from the OES measuring unit 110 as described above. Furthermore, the main control unit 112 is connected to a touch panel for man-machine interface (not illustrated), an external storage device (not illustrated) storing various setting value data or various measured value data of various programs and recipes which regulate the whole operations of the plasma processing apparatus, and the transfer control unit 206 or the process result measuring unit 208 (see, e.g., FIG. 1). In this exemplary embodiment, the main control unit 112 is shown as one control unit, but a configuration in which a plurality of control units share functions of the main control unit 112 hierarchically or in parallel, may be adopted.

In the microwave plasma processing apparatus, for example, in order to perform etching, a semiconductor wafer W to be processed is carried into the chamber 10 in a state where the gate valve 28 is opened, and placed on the electrostatic chuck 36. Then, processing gases, that is, etching gases (generally, mixed gases) are introduced into the chamber 10 from the processing gas introducing units 80, 82 in a predetermined flow rate and flow ratio, and the pressure in the chamber 10 is decompressed to a setting value by the exhaust device 26. Further, a heat transfer gas (helium gas) is supplied to a contact interface between the electrostatic chuck 36 and the semiconductor wafer W from the heat transfer gas supplying unit, and the switch 42 is turned ON to fix the semiconductor wafer W by an electrostatic attraction force. Then, the microwave generator 60 is turned ON such that the microwaves output at a predetermined power from the microwave generator 60 are propagated from the microwave transmission line 58, and fed to the radial line slot antenna 55 through the dielectric plate 56, thereby radiating the microwaves from the antenna 55 into the chamber 10. Further, the high-frequency power source 30 is turned ON to output a high frequency for RF bias at a predetermined power, and the high frequency is applied to a bias electrode through the matching unit 32 and the power feeding rod 34.

The etching gas, which is introduced from the injector 90 of the upper gas introducing unit 80 and the injection ports 98 of the lateral gas introducing unit 82 to the plasma producing space in the chamber 10, is ionized or dissociated by the microwave surface waves propagating in the radial direction along the bottom surface of the dielectric window 52 and the plasma. Therefore, the plasma produced in the vicinity of the dielectric window 52 is diffused downwards, thereby performing the isotropic etching by radicals in the plasma and/or vertical etching by ion irradiation vertical etching on the film to be processed on the main surface of the semiconductor wafer W.

[Etching by Multilayer Resist Method in Exemplary Embodiment]

Subsequently, descriptions will be made on an exemplary embodiment in which the microwave plasma processing apparatus is used for a gate etching processing for patterning a gate electrode of an MOS transistor using the multilayer resist method.

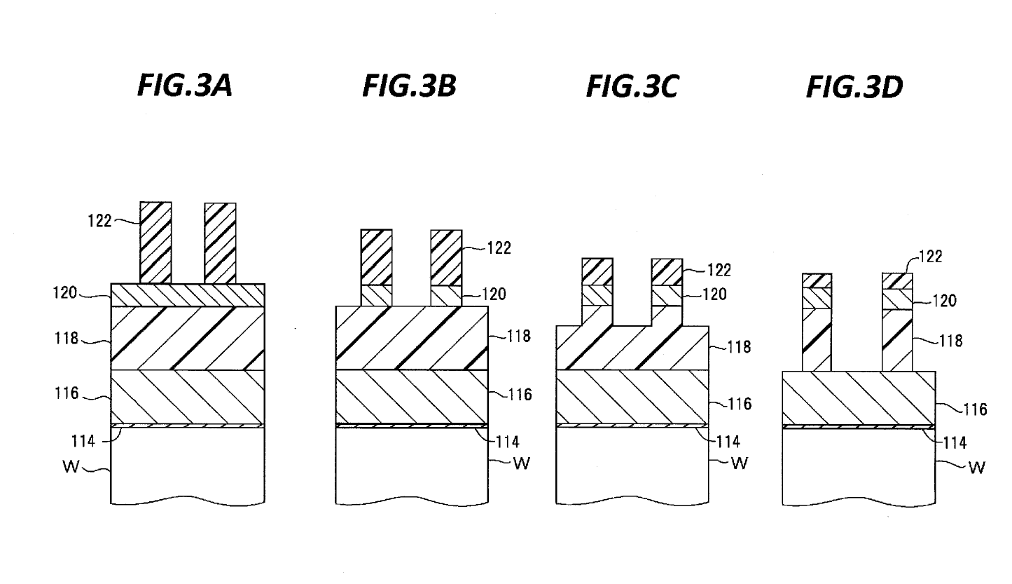

FIGS. 3A to 3D illustrate an exemplary multilayer resist method which can be performed using the microwave plasma processing apparatus. On the main surface of the semiconductor wafer W which is an object to be processed, an SiN layer 116 is formed as a bottom layer (the last mask) on the original film to be processed (e.g., a polycrystalline Si film for gate electrodes) 114. And, an organic film (e.g., carbon) 118 is formed as an intermediate layer on the SiN layer 116, and a photoresist 122 is formed as a top layer over an anti-reflection film (BARC) 120 on the organic film 118. A CVD or spin-on coating method is used for film formation of the SiN layer 116, the organic layer 118, and the anti-reflection layer 120. Photolithography is used for patterning of the photoresist 122. Meanwhile, a thermal oxide film for a gate insulation film (not illustrated) is formed under the polycrystalline Si film 114.

At first, as an etching process of a first step, as illustrated in FIGS. 3A and 3B, the anti-reflection film 120 is etched using the photoresist 122, which is patterned in advance. In this case, a mixed gas of, for example, Ar/HBr/O₂ is used as an etching gas.

Subsequently, as an etching process of a second step, as illustrated in FIGS. 3B and 3C, the surface of the organic film 118 is etched thinly using the photoresist 122 and the patterned anti-reflection film 120 as masks. In this case, a mixed gas of, for example, Ar/Cl₂ is used as an etching gas. Meanwhile, since an oxide film is deposited on the surface of the organic film 118 at the end of the first step by using O₂ for the etching gas of the first step, the etching processing is performed to remove the oxide film. Accordingly, the etching amount is relatively small, and the etching time is relatively short as well.

Finally, as an etching process of a third step, as illustrated in FIGS. 3C and 3D, a main etching of the organic film 118 is performed using the photoresist 122 and the anti-reflection film 120 as masks. In this case, a mixed gas of, for example, Ar/O₂ is used as an etching gas.

As a result, the pattern of the photoresist 122 is transferred to the organic film 118 through the anti-reflection film 120. Thereafter, although not illustrated, the remaining films of the photoresist 122 and the anti-reflection film 120 are removed by wet etching or ashing. Then, the SiN film 116 is etched using the pattern of the organic film 118 as a mask, and subsequently, the polycrystalline Si film 114 is etched using the pattern of the SiN film 116 as a mask. The subsequent steps are generally performed by a separate processing apparatus. However, the microwave plasma processing apparatus (see, e.g., FIG. 2) used for the successive etching processing of the anti-reflection film 120 and the organic film 118 may be also used for the etching processing of the SiN film 116 and/or the etching processing of the polycrystalline Si film 114.

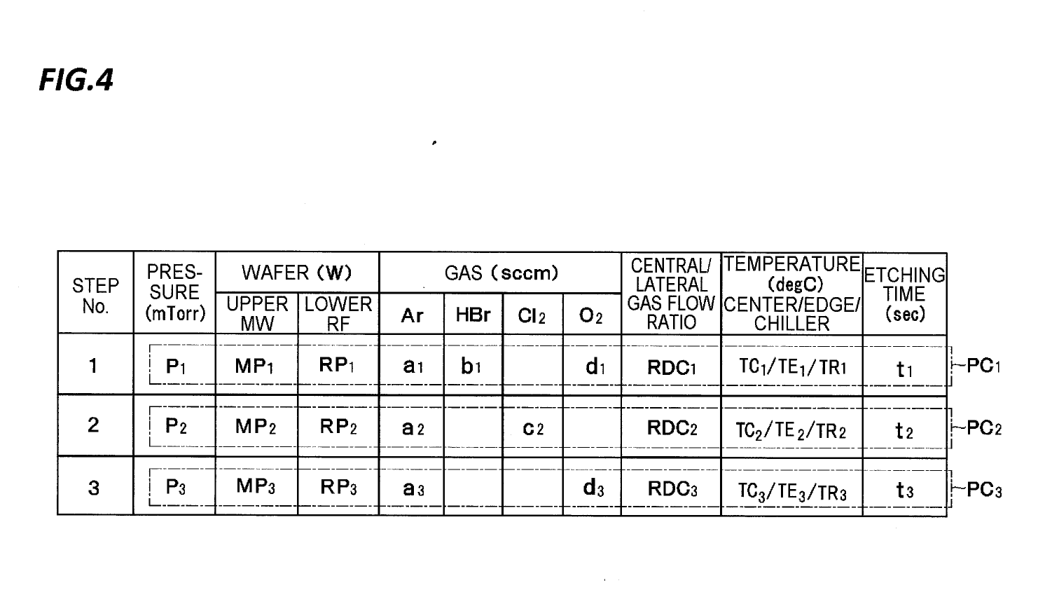

In the microwave plasma processing apparatus of this exemplary embodiment, in a case where an etching processing is performed by the multilayer resist method as described above, a recipe, for example, as illustrated in FIG. 4 is prepared in advance, and data of the recipe is stored in a memory in the main control unit 112 or an external storage device. The main control unit 112 refers to the data of the recipe stored in the internal memory or the external storage device, and controls the respective units in the apparatus (e.g., the exhaust device 26, the microwave generator 60, the high-frequency power source 30, the processing gas supply source 86, and the MFCs 92, 102).

According to the recipe of FIG. 4, in the first step, the pressure in the chamber 10 is set to P₁ (mTorr), the power of the upper microwave (upper MW) supplied to the radial line slot antenna 55 is set to MP₁ (W), the power of the lower high frequency applied to the susceptor 12 (lower RF) is set to RP₁ (W), the flow rate of the etching gases (Ar/HBr/O₂) is set to a₁/b₁/d₁ (sccm), the central/lateral gas flow ratio between the upper gas introducing unit 80 and the lateral gas introducing unit 82 is set to RDC₁, the center/edge/chiller temperatures of the stage (lower electrode) are set to TC₁/TE₁/TR₁ (deg C), and the etching time is set to t₁ (sec).

In the second step, the pressure is set to P₂ (mTorr), the power of the upper microwave (upper MW) is set to MP₂ (W), the power of the lower high frequency (lower RF) is set to RP₂ (W), the flow rate of the etching gases (Ar/Cl₂) is set to a₂/c₂ (sccm), the central/lateral gas flow ratio is set to RDC₂, the center/edge/chiller temperatures of the stage (lower electrode) are set to TC₂/TE₂/TR₂ (deg C), and the etching time is set to t₂ (sec).

In the third step, the pressure is set to P₃ (mTorr), the power of the upper microwave (upper MW) is set to MP₃ (W), the power of the lower high frequency (lower RF) is set to RP₃ (W), the flow rate of the etching gases (Ar/O₂) is set to a₃/d₃ (sccm), the central/lateral gas flow ratio is set to RDC₃, the center/edge/chiller temperatures of the stage (lower electrode) are set to TC₃/TE₃/TR₃ (deg C), and the etching time is set to t₃ (sec).

In the recipe, the process conditions (electric power, gas species, gas flow rate, central/lateral gas flow ratio, temperature, etching time) are independently set for each of the first, second and third steps. However, some setting values of certain process conditions frequently become equal to each other in different steps.

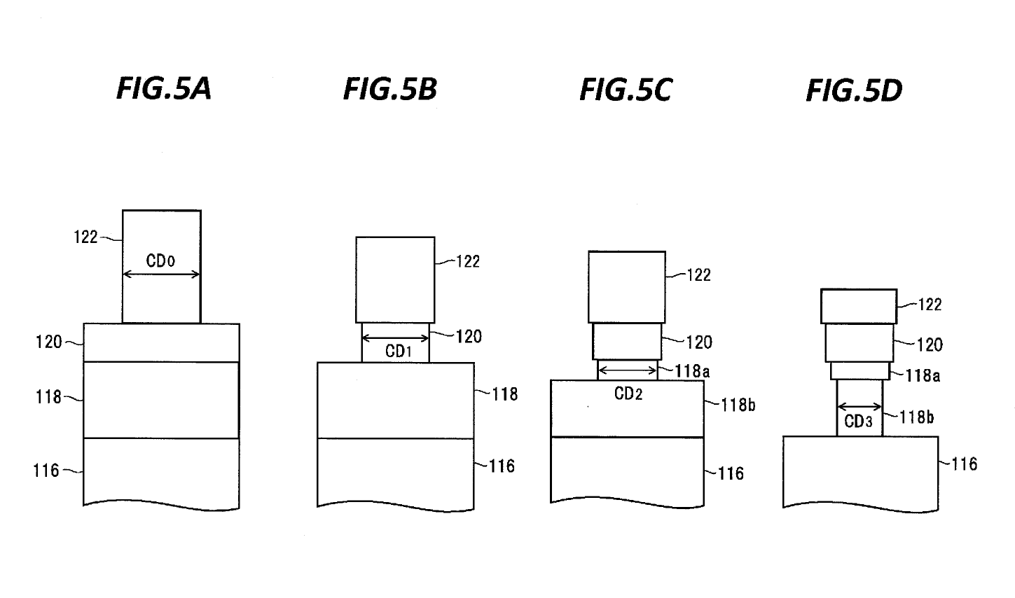

Further, in this exemplary embodiment, a target CD value (e.g., bottom CD) is set for each of the first, second and third steps in the recipe, or separately from the recipe. That is, as illustrated in FIG. 5, in the etching processing in the multilayer resist method, a pattern critical dimension of a photoresist 122 is measured in advance by a scanning electron microscope (SEM), and the measured CD value is set as an initial value CD₀. With respect to the initial value CD₀, a short pattern dimension of an anti-reflection film 120 by the etching of the first step is set as a first target value CD₁, a short upper pattern dimension of an organic film 118a by the etching of the second step is set as a second target value CD₂, and a short main pattern dimension of an organic film 118b by the etching of the third step is set as a third target value CD₃. The initial value CD₀ and the first, second and third target values CD₁, CD₂, CD₃ are stored in the internal memory of the main control unit 112 or an external storage device.

Meanwhile, in order to cope with the miniaturization of MOS transistors, a method in which, as illustrated in FIGS. 5A to 5D, the CD is made smaller whenever the CD goes through etching processing steps to be close to the final target CD (gate CD), is generally adopted. However, it is also possible to maintain the CD at the same value through all the steps, or to make the CD gradually larger whenever the CD goes through the steps.

[Exemplary Embodiment 1 of APC]

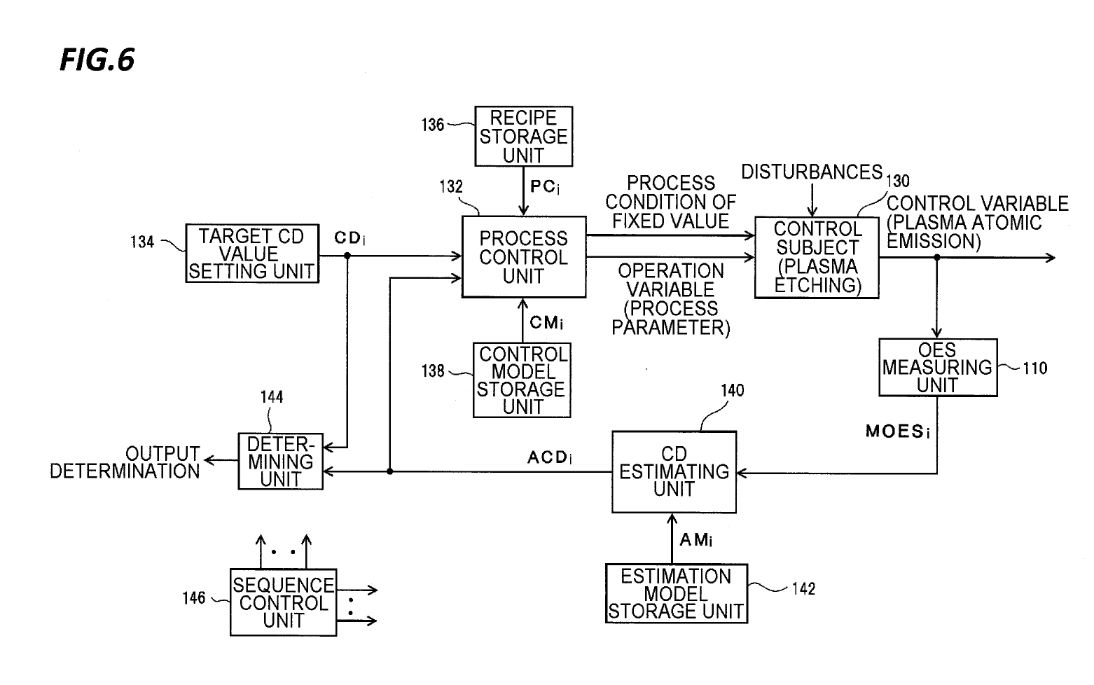

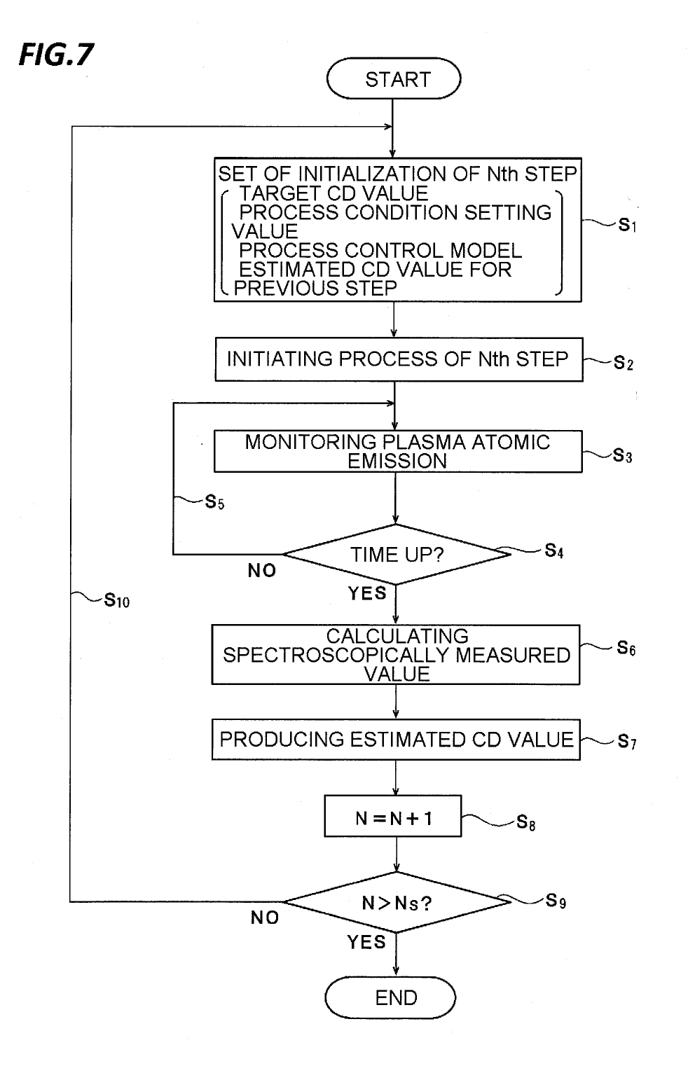

FIG. 6 illustrates a preferred exemplary embodiment of an APC mechanism which can be mounted in the microwave plasma processing apparatus in order to perform the etching processing in the multilayer resist method as described above (see, e.g., FIG. 3). The APC mechanism is configured by the OES measuring unit 110, and hardware (specifically, a CPU, an internal memory, and an interface) and software (a program, an algorithm, setting values, and measuring data) in the main control unit 112. FIG. 7 illustrates a main processing procedure of the APC mechanism.

In the APC mechanism, a control subject 130 is an etching process which is performed in the chamber 10, and undergoes various disturbances. A process control unit 132 receives a target CD value CDᵢ (i=1, 2, 3) from a target CD value setting unit 134 in each step, and controls the etching process 130 serving as the control subject so as to obtain the CD that is the same as or close to the target value CDᵢ. Here, the process control unit 132 receives a process condition setting value PCᵢ (see, e.g., FIG. 4) from a recipe storage unit 136 in each step, receives a process control model CMᵢ for each step from a control model storage unit 138, and uses the process condition setting value PCᵢ and the process control model CMᵢ for automatic control of the etching process 130 serving as the control subject (S₁, S₂ in FIG. 7). The process control models CMᵢ and the process conditions, particularly, the process parameters as operation variables will be described later in detail.

An output or a control variable of the etching process 130 serving as the control subject is plasma atomic emission, and is monitored by the OES measuring unit 110 during the etching processing in each step (S₃→S₄→S₅→S₃→ . . . in FIG. 7). The OES measuring unit 110 in this exemplary embodiment outputs a spectroscopically measured value MOESᵢ for each step at the end of or immediately after each step (S₄→S₆ in FIG. 7). For example, the OES measuring unit 110 calculates an average value, an integral value, or an instantaneous value in a predetermined timing (e.g., immediately before the completion of the step) in terms of the intensity of a specific spectrum having a high correlation with plasma etching, as a spectroscopically measured value MOESᵢ for each step. Here, in order to compensate for a temporal change of measured environment such as a monitor window dirt, the spectroscopically measured value MOESᵢ for each step may be obtained by taking a ratio of an intensity of the spectrum which has a high correlation with plasma etching as described above and an intensity of a spectrum which has no or very little correlation with plasma etching, and calculating the average value, the integral value, or the instantaneous value in a predetermined timing in terms of the ratio. Alternatively, the spectroscopically measured value MOESᵢ for each step may be obtained as a temporal integral value of the total of all spectra (intensity) included in a certain wavelength range.

A CD estimating unit 140 receives a CD estimation model AMᵢ for each step from an estimation model storage unit 142 in each step, and obtains an estimated CD value ACDᵢ for each step using the CD estimation model AMᵢ and the spectroscopically measured value MOESᵢ from the OES measuring unit 110 after the completion of each step (S₇ in FIG. 7). The CD estimation model AMᵢ will be described later in detail.

Thus, the estimated CD value ACDᵢ produced in the CD estimating unit 140 immediately after the completion of each step is given as a feedforward signal to the process control unit 132. The process control unit 132 uses the estimated CD value ACDᵢ received from the CD estimating unit 140 in the next step. That is, in the next step, the process control unit 132 uses an estimated CD value for the previous step (or deviation ΔCD₁=CD₁−ACD₁) which is received from the CD estimation model 140, in addition to a process condition setting value PCᵢ₊₁ for the next step which is received from the recipe storage unit 136, and a process control model CMᵢ₊₁ for the next step which is received from the control model storage unit 138, for automatic control of the control subject (the etching process 130) (S₈→S₉→S₁₀→S₁ in FIG. 7).

For example, when the deviation (ΔCD₁=CD₁-ACD₁) is a positive (+) value, the estimated value ACDᵢ is smaller than the first target value CD₁ in the first step. That is, it is estimated that the CD of the anti-reflection film 120 as an etching result of the first step is set to a smaller value than the first target value CD₁ in the etching processing in the multilayer resist method (see, e.g., FIG. 3). The CD of the anti-reflection film 120 becomes a mask dimension (reference value) for the etching of the organic film 118 in the next second step. Accordingly, in a case where the CD of the anti-reflection film 120 is actually smaller than the first target value CD₁, when the etching of the next second step is performed according to the recipe, the short upper pattern dimension of the organic film 118 becomes securely smaller than the second target value CD₂ at the end of the second step. Therefore, the process control unit 132 targets the CD to be slightly larger than the second target value CD₂ in consideration of the deviation ΔCD₁, and adjusts process parameters of the operation variables among the process condition setting values PC₂ for the second step.

On the contrary, when the deviation (ΔCD₁=CD₁−ACD₁) is a negative (−) value, the estimated value ACDᵢ is larger than the first target value CD₁ in the first step, and in this case, the compensation is performed reversely. That is, the process control unit 132 targets the CD to be slightly smaller than the second target value CD₂ in light of the negative (−) deviation ΔCD₁, and adjusts process parameters of the operation variables among the process condition setting values PC₂ for the second step.

In FIG. 6, in order to determine quality of the etching processing, a determining unit 144 receives the target value CDᵢ from the target CD value setting unit 134 and the estimated CD value ACDᵢ from the CD estimating unit 140 and inspects the difference or deviation ΔCDᵢ of both in each step. Then, when the deviation ΔCDᵢ is within a tolerable range, it is determined that the etching processing in the corresponding step is good, or otherwise (when the deviation ΔCDᵢ is deviated from the allowable range), it is determined that the etching processing in the corresponding step is poor.

Nevertheless, even though the first step and/or the second step are poor, when the determination result for the last third step is good, it may be determined that the single-wafer etching processing is resultantly good this time. On the contrary, even though the first step and the second step are all good, when the determination result for the last third step is poor, it may be determined that the single-wafer etching process is poor this time. The main control unit 112 determines whether to continue or stop the subsequent single-wafer etching processing based on the determination result obtained from the determining unit 144.

A sequence control unit 146 controls timing of each unit in the APC mechanism such that respective units are operated in cooperation with each other according to the processing sequence as described above.

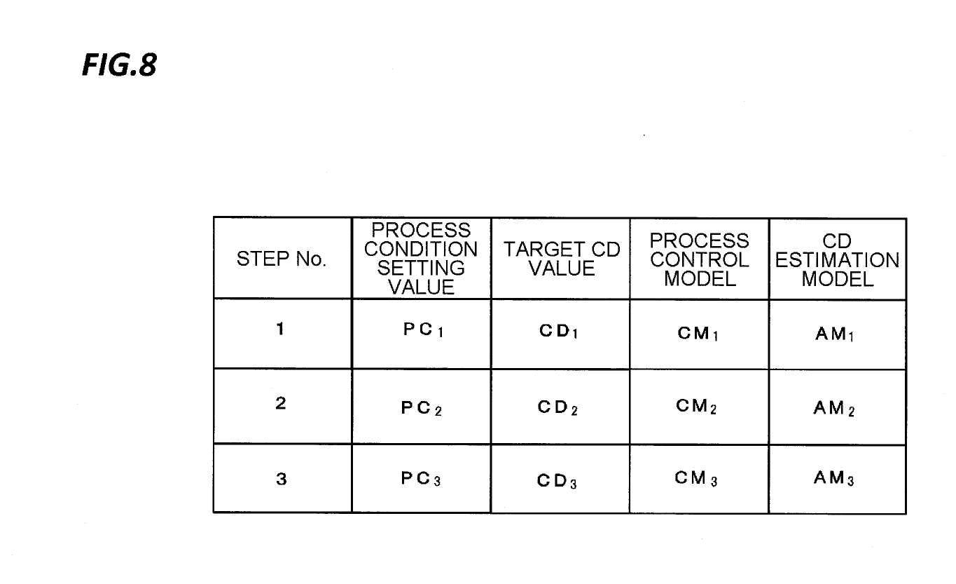

As described above, the APC mechanism in this exemplary embodiment is provided with the CD estimating unit 140 and the process control unit 132. Here, the CD estimating unit 140 uses the CD estimation model AMᵢ to estimate the value of the CD for the corresponding step from the spectroscopically measured value MOESᵢ obtained from the OES measuring unit 110 after the completion of each step. Meanwhile, the process control unit 132 uses the process control model CMᵢ to adjust predetermined process parameters selected from the process conditions based on the target CD value CDᵢ₊₁ for the next step given from the target CD value setting unit 134 in the next step of each step and the estimated CD value ACDᵢ for each step given from the CD estimating unit 140. That is, correction is performed on the setting values of the process parameters. Then, in every step, the process condition setting value PCᵢ, the target CD value CDᵢ and the process control model CMᵢ used in the process control unit 132 are switched, and the CD estimation model AMᵢ used in the CD estimating unit 140 is switched. This structure is shown in the table of FIG. 8.

As described above, since the APC mechanism in this exemplary embodiment performs all of the setting of the target CD value, the spectroscopic measurement of the plasma atomic emission, the estimation of the values of the process result, and the adjustment of the process parameters in a step unit, an APC may be established so as to perform an inter-step control during one single-wafer etching process by the multilayer resist method. Further, the process control model CMᵢ used in the process control unit 132 and the CD estimation model AMᵢ used in the CD estimating unit 140 are switched in every step. By providing the APC mechanism, the microwave plasma processing apparatus in this exemplary embodiment may precisely suppress a process performance state which cannot be stabilized only by setting the process conditions, or variation in apparatus state which cannot be dealt with hardware, and perform a multistep etching process without any fluctuation or unevenness such that the CD after the completion of the whole steps becomes the same as or close to the target value as far as possible. Accordingly, a machine error may be eliminated between apparatuses or modules to suppress a process variation.

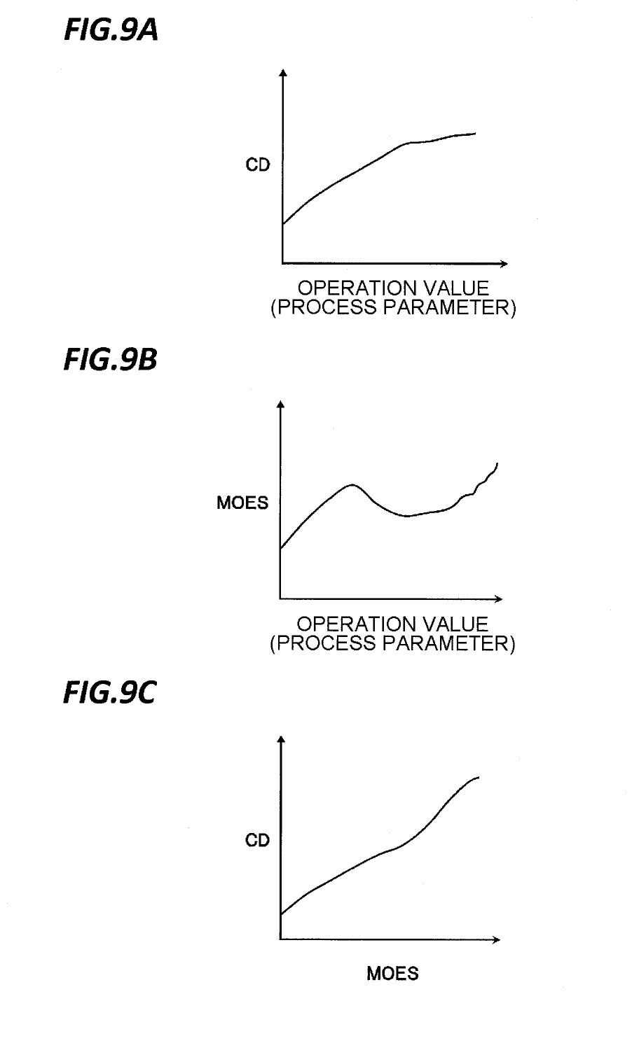

In the APC mechanism in this exemplary embodiment, the CD estimation model AMᵢ used in the CD estimating unit 140 is preferably a statistical model obtained by a multivariate analysis using a design of experiments (DOE). For example, from statistical data or experimental data, a first function (see, e.g., FIG. 9A) representing a correlation between a process parameter of an operation variable and a measured CD value is acquired, and a second function (see, e.g., FIG. 9B) representing a correlation between the process parameter of the operation variable and a spectroscopically measured value MOES is acquired. Then, from the first function (see, e.g., FIG. 9A) and the second function (see, e.g., FIG. 9B), a third function, that is, a CD estimation model AM (see, e.g., FIG. 9C) representing a correlation between the spectroscopically measured MOES and the estimated CD value ACD is prepared.

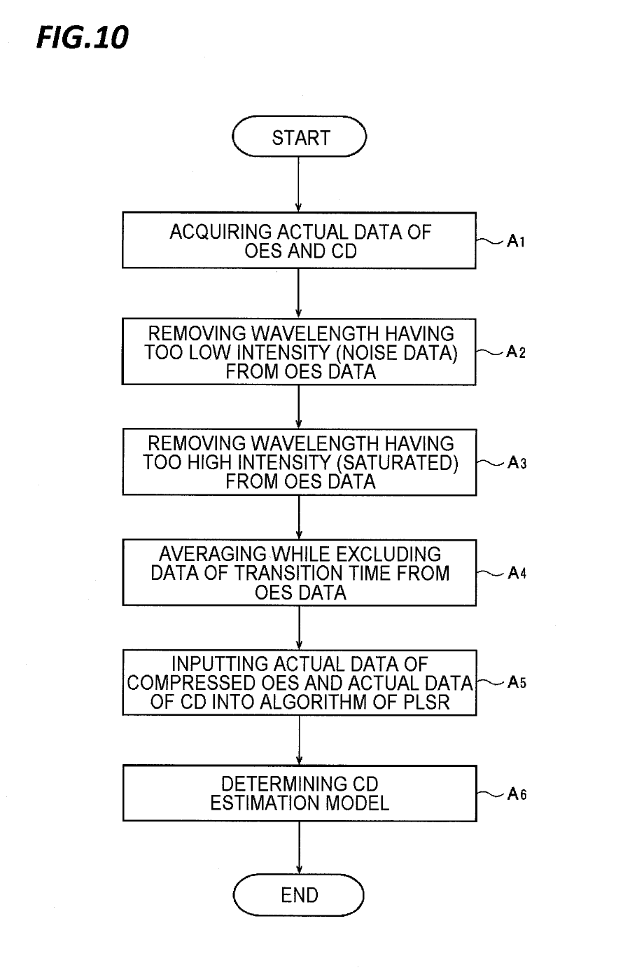

As another method for establishing the CD estimation model AM, a multivariate analysis, for example, a partial least squares regression (PLSR), may be preferably used. FIG. 10 illustrates a sequence of establishing the CD estimation model by the PLSR method.

First, through an actual process or experiment of the plasma etching based on a given recipe which is performed on a plurality (preferably 10 sheets or more) of semiconductor wafers, actual data of the OES and CD are acquired from the OES measuring unit 110 and the process result measuring unit 208, respectively (A₁ in FIG. 10).

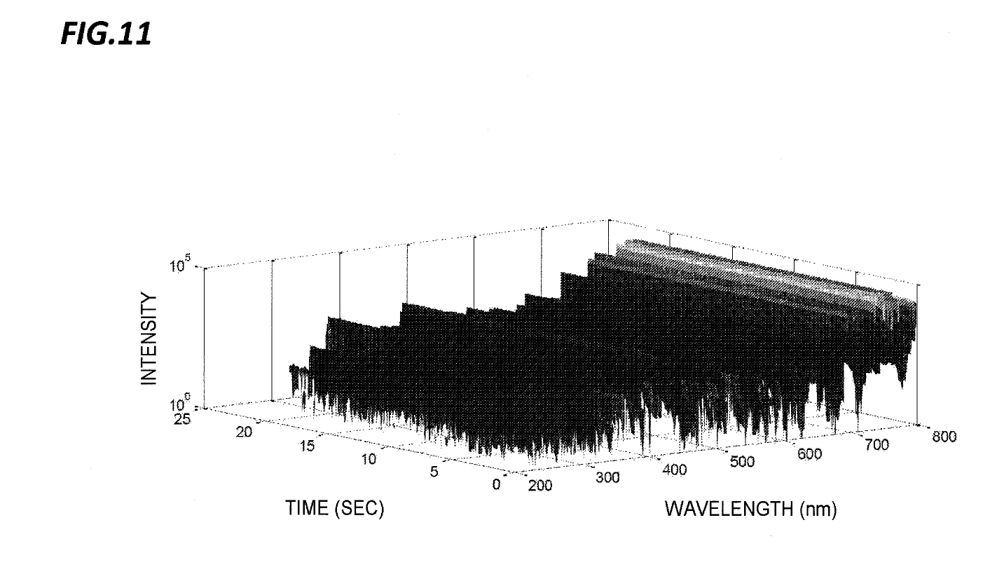

The OES data (the spectroscopically measured value MOES) obtained from the OES measuring unit 110 is given as a three-dimensional spectrum on a wavelength axis and a time axis, as illustrated in FIG. 11. For example, when it is assumed that a wavelength measurement range is 200 nm to 800 nm and a measurement resolution is 0.5 nm, light intensities for 1,201 wavelengths are measured on the wavelength axis. Further, when it is assumed that a sampling time is, for example, 0.1 seconds, and when the process time is 50 seconds, a total of 500 OES data for each wavelength is obtained every 0.1 seconds from the start of the process until the end.

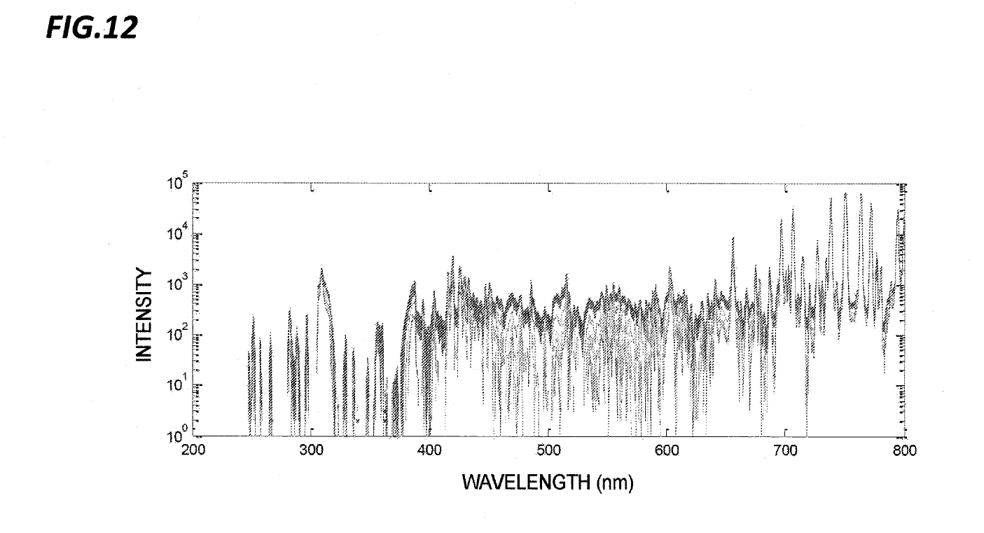

As such, the OES data obtained from the OES measuring unit 110 in one process is enormous. Therefore, it is desirable to perform a data compression (filtering processing) on the OES data. Specifically, when observed at a certain point in time, the spectrum of 200 nm to 800 nm is greatly varied as illustrated in FIG. 12. This tendency is almost unchanged throughout the entire time of the process. Thus, from the OES data, a filtering processing to remove wavelengths having relatively too low intensity (A₂ in FIG. 10), and a filtering processing to remove wavelengths having relatively too high intensity (which are saturated, for example) (A₃ in FIG. 10) are performed. By these filtering processings, the 1,201 wavelengths to be observed may be reduced to about 400 wavelengths.

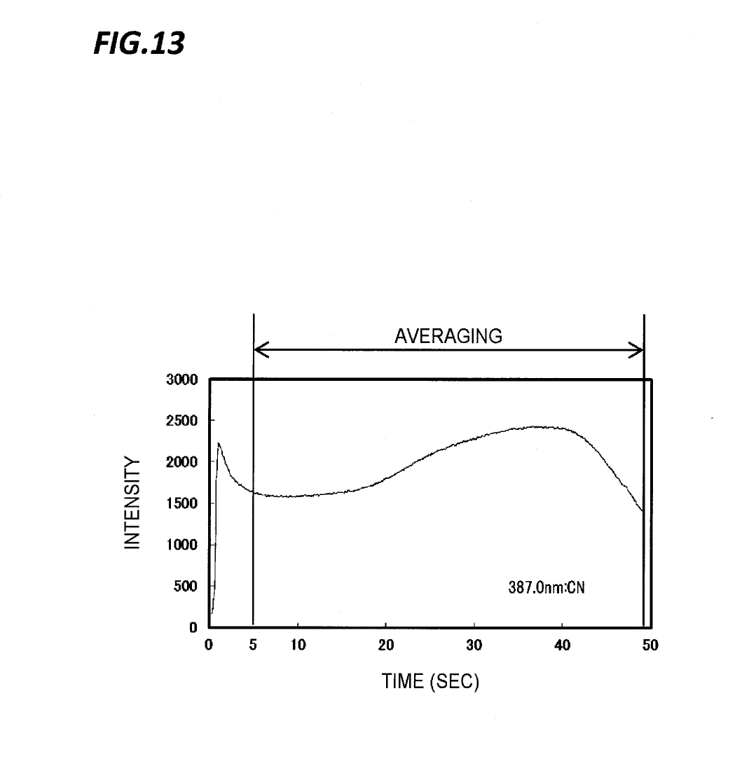

Further, as illustrated in FIG. 13, on the time axis, the light intensity of each wavelength is rising rapidly immediately after the start of the process. Thus, overshoot is likely to occur, and it will take a while for stabilization. Therefore, an average is obtained, excluding such a transition time (5 seconds in the illustrated example) (A₄ in FIG. 10). Accordingly, the OES data may be further compressed. Meanwhile, FIG. 13 is a plot illustrating a change in a nitrogen carbide (CN) spectrum (387.0 nm) on a time axis, which is acquired in the etching process of the second step. The same transition property is observed in other spectra.

Then, from the actual data of the OES compressed as described above and the actual data of the CD, a regression coefficient bⱼ (j=0, 1, . . . p) of the CD estimation model AM expressed by the following Equation (1) of a regression analysis is obtained by an algorithm of the PLSR on an off-line computer (A₅ and A₆ in FIG. 10).

CD=b₀+b₁*X₁+b₂*X₂+ . . . +bₚ*Xₚ (1)

However, Xⱼ (j>0) is a light intensity (average) of each wavelength (λⱼ) included in the compressed OES data. In the above example, when wavelengths of the OES data are compressed to 400 wavelengths, the last term is p=399.

Even if the OES data is pre-processed, the number of the data as illustrated in FIG. 12 is hundreds, and strong multicollinearity is observed (the value of the regression coefficient becomes unstable, and thus, prediction accuracy is deteriorated).

Multiple regression may be used for a data analysis including a number of factors (wavelengths). However, when the number of factors is excessive, over-fitting occurs, thereby deteriorating the prediction accuracy. Accordingly, in order to avoid the multicollinearity and the over-fitting, an estimation model is established using the PLSR or PCR.

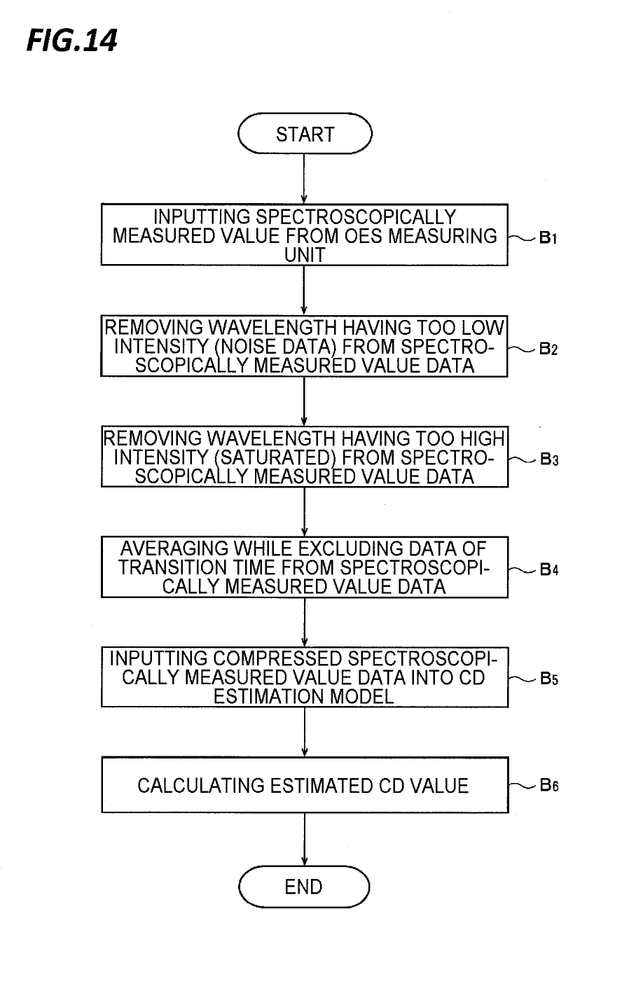

The CD estimation model AM established by the PLSR method as described above is stored in the estimation model storage unit 142 of the APC mechanism (see, e.g., FIG. 6) in the plasma processing apparatus of the present exemplary embodiment (see., e.g., FIG. 2). And, in the actual plasma etching, when the estimated CD value ACD is obtained using the CD estimation model AM of the PLSR, a signaling processing as illustrated in FIG. 14 is performed on line.

That is, with respect to the OES data (the spectroscopically measured value MOES) obtained from the OES measuring unit 110 (B₁ in FIG. 14), a filtering processing excluding wavelengths having relatively too low intensity (B₂ in FIG. 14), and a filtering processing excluding wavelengths having relatively too high intensity (which are saturated, for example) (B₃ in FIG. 10) are performed in the same manner as described above in the CD estimating unit 140 (or the OES measuring unit 110). Further, an averaging processing is performed excluding a transition time (B₄ in FIG. 14). And, the OES data compressed thereby, that is, the light intensity (average) data for p (400) wavelengths is set to an independent variable of the CD estimation model of the PLSR represented by Equation (1) in the CD estimating unit 140 (B₅ in FIG. 14), and thus, the estimated CD value of a dependent variable is calculated (B₆ in FIG. 14).

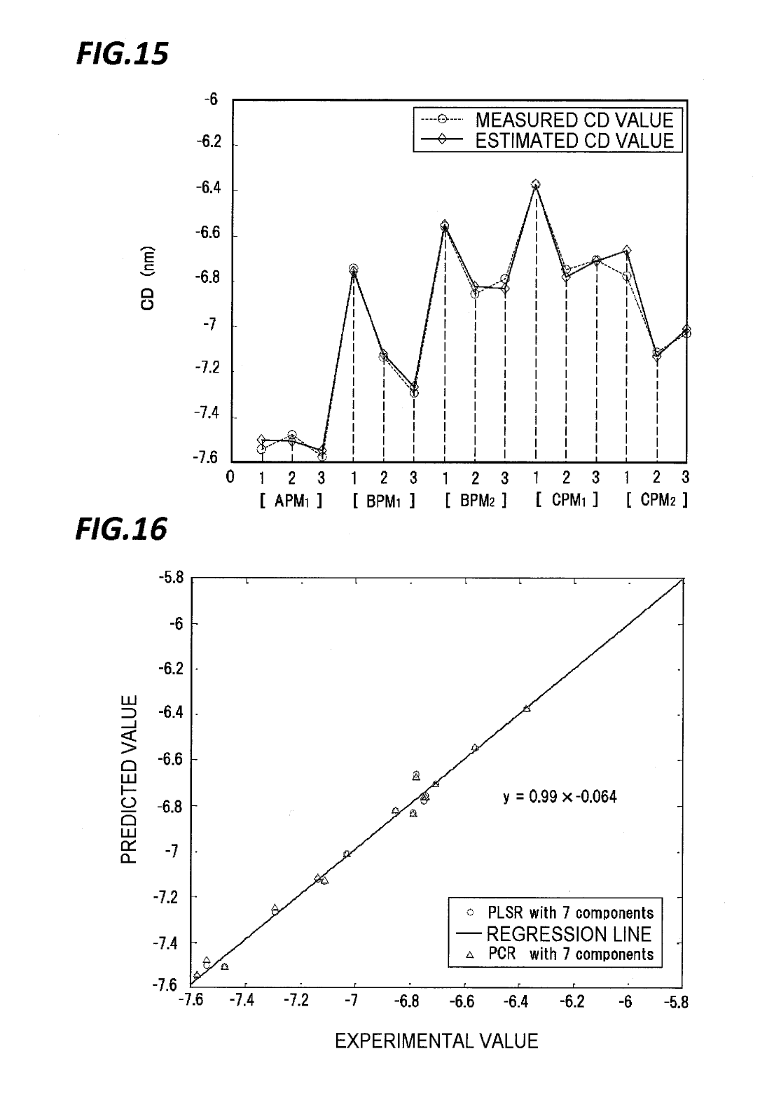

FIG. 15 is a diagram in which an estimated CD value and a measured CD value are plotted in which the measured CD value is measured by the PLSR using the data set obtained when the etching processing of the second step is performed with the same recipe in a first process module APM₁ of a cluster tool A, first and second process modules BPM₁, BPM₂ of a cluster tool B, and first and second process modules CPM₁, CPM₂ of a cluster tool C, which are the plasma etching apparatuses (see, e.g., FIG. 2) of the same model. In the graph, the number 1, 2, 3 on the horizontal axis are a processing order of wafers on which the etching process of the same recipe is performed successively in each process module. Further, the numbers on the vertical axis are values (estimated values and measured values) of the CD.

As illustrated, with respect to the CD in the etching process, it is found that a machine error between apparatuses and a machine error between chambers obviously exist, and despite the machine errors, the estimated CD values in the PLSR method are approximate to the measured CD values with high accuracy. In FIG. 15, a mean absolute percentage error (MAPE) is −0.4, and a root mean square error (RMSE) is 0.038.

Performing a regression analysis (least squares method) on the data correlation (graph) of FIG. 15 leads to a graph as illustrated in FIG. 16. In FIG. 16, the regression line is represented by y=0.99x−0.64, and R²=0.988. Meanwhile, FIG. 16 illustrates a regression analysis of a principal least squares regression (PCR) in conjunction with the regression analysis of the PLSR. Therefore, a multivariate analysis other than the PLSR may be appropriately used for establishing the CD estimation model AM.

In this exemplary embodiment, the CD estimation models AMᵢ are independently set depending on the process conditions in each step in the etching processing of the multilayer resist method. That is, for example, the CD estimation models (mathematical formulas and/or coefficients) of the PLSR are independently established or set for each step such that the CD of the process result is precisely estimated from the plasma atomic emission state for the etching process in each step in response to the process conditions independently set for each step.

The process control models CMᵢ used in the process control unit 132 are also preferably statistical models obtained by the multivariate analysis using the design of experiments (DOE). In this exemplary embodiment, the process control models CMᵢ are independently set for each step depending on the process conditions in the etching processing of the multilayer resist method. That is, the process parameters of the operation variables are adjusted depending on the process conditions independently set for each step in consideration of the estimated value ACDᵢ₋₁ for the previous step, so as to obtain the CD which is the same as or close to the target value CDᵢ. Meanwhile, for the initial (first) step, since an estimated value for the previous step originally does not exist, it is not necessary to take it into account.

In this exemplary embodiment, the process parameters of medium variables are also independently set or selected for each step in conjunction with the process conditions being independently set for each step. Generally, the process parameters are selected based on experiments. For example, sensitivity may be determined for respective parameters by individually selecting the parameters for the process conditions set for each step and measuring a variation amount of the process result (CD) when each of the parameter is varied in a predetermined amount near the setting value or a predetermined reference value thereof. Accordingly, the ranking of the respective sensitivities may be determined among all the process conditions. Among them, the optimal sensitivity (usually one, but possibly more than one) may be selected as a process parameter of the medium variable.

For example, in the etching processing of the multilayer resist method, when the recipe as illustrated in FIG. 4 is prepared, among the process conditions of the first step, the most sensitive process condition is the O₂ flow rate, the second most sensitive one is the HBr flow rate, and the third most sensitive one is the lower RF power. The sensitivities of other process conditions (e.g., pressure, upper MW, temperature, and time) are generally low. Accordingly, any one or more of the O₂ flow rate, the HBr flow rate, and the lower RF power may be selected as a process parameter of the first step.

Further, among the process conditions of the second step, the sensitivities of the Cl₂ flow rate and the lower RF power are overwhelmingly high. Other process conditions (e.g., pressure, upper MW, temperature, and time) are generally low. Accordingly, any one or both of the Cl₂ flow rate and the lower RF power may be selected as a process parameter of the second step.

Further, among the process conditions of the third step, the sensitivities of the O₂ flow rate and the lower RF power are overwhelmingly high. Other process conditions (e.g., pressure, upper MW, temperature, and time) are generally low. Accordingly, any one or both of the O₂ flow rate and the lower RF power may be selected as a process parameter of the third step.

### Another Exemplary Embodiment or Modified Embodiment

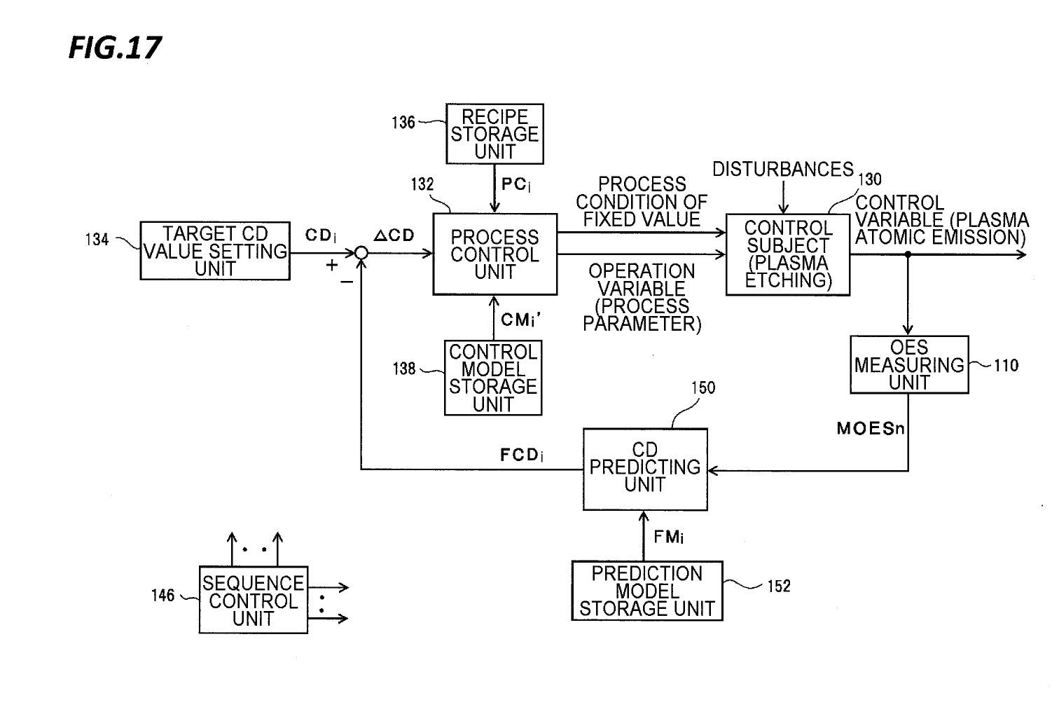

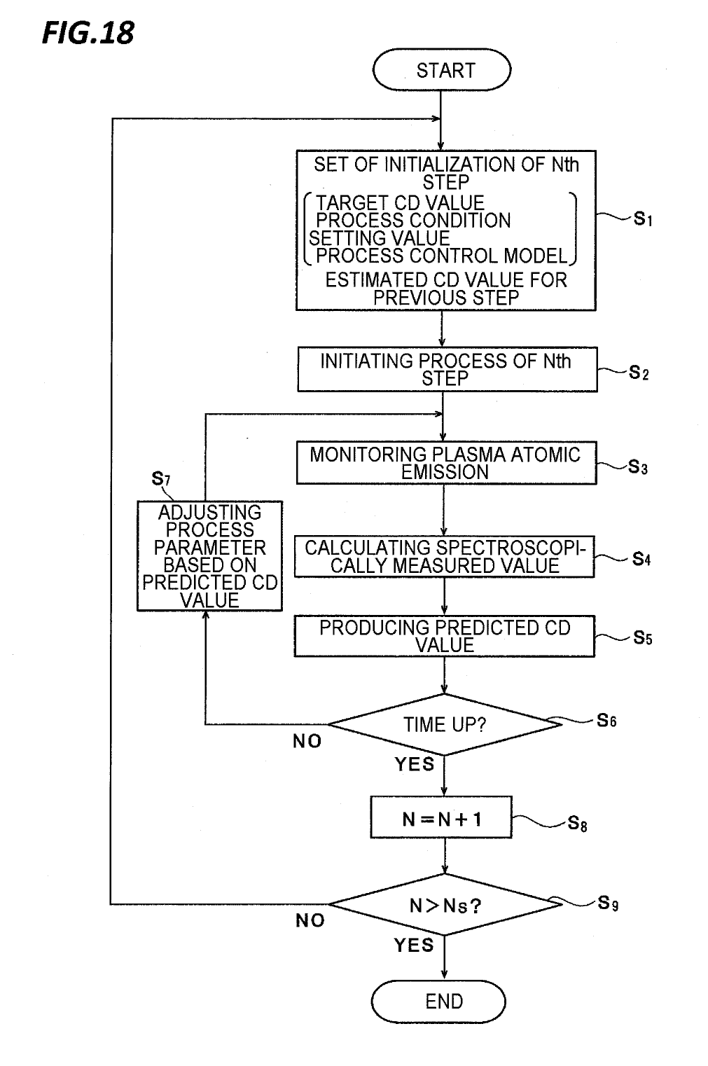

FIG. 17 illustrates another preferred exemplary embodiment of the APC mechanism which can be mounted in the microwave plasma processing apparatus in order to perform the etching processing (see, e.g., FIG. 3) of the multilayer resist method as described above. In the figure, the same reference numerals are given to parts having the same configuration or function as in the APC mechanism (see, e.g., FIG. 6) in the first exemplary embodiment. FIG. 18 illustrates a main processing procedure of the APC mechanism in the second exemplary embodiment.

In this exemplary embodiment, the OES measuring unit 110 outputs a spectroscopically measured value MOESₙ at a certain period of time Tₙ (e.g., 100 msec) (S₃ and S₄ in FIG. 18). Accordingly, the spectroscopically measured value MOESₙ may be an instantaneous value, an arithmetic mean value, or an integral value at each sampling point of time in terms of an intensity of a specific spectrum having a high correlation with plasma etching. Alternatively, the spectroscopically measured value MOESₙ may be an instantaneous value, an arithmetic mean value, or an integral value at each sampling point of time in terms of the total of all spectra (intensity) included in a certain wavelength range.

A CD predicting unit 150 receives a CD prediction model FMᵢ for each step from a prediction model storage unit 152 in each step, and obtains a predicted CD value FCDᵢ for each step using the CD prediction model FMᵢ and the spectroscopically measured value MOESᵢ sequentially given at a certain time Tₙ interval from the OES measuring unit 110 during the process of each step (S₇ in FIG. 18). The CD prediction model FMᵢ is preferably a statistical discrete time model determined by a multivariate analysis using a design of experiments (DOE). For example, the discrete time-typed CD prediction model FMᵢ may be prepared by incorporating a time parameter into the CD prediction model FM.

Thus, the spectroscopically measured value MOESₙ is given as a feedback signal to the process control unit 132 from the OES measuring unit 110 at every predetermined time interval Tₙ during the process of each step. The process control unit 132 adjusts process parameters of the operation variables according to the spectroscopically measured value MOESₙ given from the OES measuring unit 110 at every predetermined time interval Tₙ, so that a deviation ΔCD between the target value CDᵢ and the predicted value FCDₙ comes close to zero. Since the APC mechanism in this exemplary embodiment performs the setting of the target CD value, the spectroscopic measurement of the plasma atomic emission, the prediction of the CD and the adjustment of the process parameters in a predetermined interval of time, it is possible to establish an APC which performs a real-time control.

The process control model CMᵢ′ is also preferably a statistical discrete time model determined by a multivariate analysis using a design of experiments (DOE). For example, the discrete time-typed process control model CMᵢ′ may be prepared by incorporating a time parameter into the process control model CM in the first exemplary embodiment.

In the plasma processing apparatus of the exemplary embodiment, the main control unit 112 may acquire a measured CD value from the process result measuring unit 208 (see, e.g., FIG. 1) provided in the cluster tool system. The measured CD value may preferably include respective measured CD values for the first, second and third steps. Accordingly, it is possible to perform a feedback control or a feedforward control in Run-2-Run method by applying the measured CD value obtained in a wafer unit or a lot unit from the process result measuring unit 208 to the process control unit 132, and it is also possible to use the run-2-run method in combination with the APC mechanism of the above-described exemplary embodiment. Further, the APC mechanism of the above-described exemplary embodiment may be provided with a learning function to correct the process control model CIA, the CD estimation model AMᵢ, and the CD prediction model FMᵢ based on the measured CD value from the process result measuring unit 208.

The above-described exemplary embodiment related to an etching processing of a multilayer resist method. However, the present disclosure may be applied to any plasma process which divides a single-wafer plasma processing for one substrate to be processed into a plurality of steps, and set process conditions independently for each step. For example, the present disclosure may be applied to a plasma CVD or plasma ALD which changes process conditions during one single-wafer film forming processing to form a plurality of thin films. Accordingly, the process result in the present disclosure includes not only the CD but also, for example, a shape or in-plane uniformity in the etching processing, or a thickness or composition in the film forming processing.

Further, the present disclosure (especially, the real-time APC of the second exemplary embodiment) may also be applied to a single-step plasma process. The present disclosure is appropriately applied to a plasma processing apparatus which is assembled to a multi-chamber system similar to the cluster tool type apparatus, as well as a stand-alone plasma processing apparatus or plasma processing method.

The plasma processing apparatus of the present disclosure is not limited to the microwave plasma apparatus in the exemplary embodiment, but may be an inductively-coupled plasma processing apparatus or a capacitively-coupled plasma processing apparatus. Accordingly, the plasma processing method of the present disclosure may be applied to an inductively-coupled plasma processing method or a capacitively-coupled plasma processing method.

The substrates to be processed in the present disclosure are not limited to semiconductor wafers, but may be various substrates for flat panel displays, organic ELs and solar cells, or photomask, CD substrates, and print substrates.

### DESCRIPTION OF SYMBOL

10: chamber
12: susceptor
30: high-frequency power source (for RF bias)
55: radial line slot antenna
86: processing gas supply source
80: upper gas introducing unit
82: lateral gas introducing unit
110: OES measuring unit
112: main control unit
132: processing control unit
134: target CD value setting unit
136: recipe storage unit
138: control model storage unit
140: CD estimating unit
142: estimation model storage unit
144: determining unit
146: sequence control unit
150: CD predicting unit
152: prediction model storage unit
208: process result measuring unit

1. A plasma processing apparatus in which a plasma processing for a substrate to be processed is divided into a plurality of steps and process conditions are independently set for each step, the apparatus comprising:
an evacuable processing container configured to removably accommodate the substrate;
a plasma generating unit configured to generate plasma of a processing gas in the processing container in accordance with the process conditions for each step;
a target value setting unit configured to set a target value for each step on a determined process result;
a plasma measuring unit configured to spectroscopically measure atomic emission of the plasma generated in the processing container;
a process result estimating unit configured to estimate a value of the process result in a corresponding step from a spectroscopically measured value obtained from the plasma measuring unit after the completion of each step; and
a process control unit configured to adjust at least one of the process conditions as a process parameter in a next step of each step, based on the target value of the process result for the next step given from the target value setting unit and an estimated value of the process result for each step given from the process estimating unit.

2. The plasma processing apparatus of claim 1, wherein the process result estimating unit obtains an estimated value of the process result using a first statistical model obtained from a multiple regression analysis using design of experiments.

3. The plasma processing apparatus of claim 2, wherein the first statistical model is set in accordance with the process conditions and the process parameter, and switched in each step.

4. The plasma processing apparatus of claim 1, wherein the process control unit determines a corrected value of the process parameter using a second statistical model obtained by a multiple regression analysis using design of experiments.

5. The plasma processing apparatus of claim 4, wherein the second statistical model is set in accordance with the process condition and the process parameter, and switched in each step.

6. The plasma processing apparatus of claim 2, further comprising a process result measuring unit configured to measure a value of the process result, wherein the first statistical model is corrected based on the measured value of the process result obtained from the process result measuring unit.

7. The plasma processing apparatus of claim 1, further comprising a determining unit configured to determine quality of the plasma processing for the substrate based on the estimated value of the process result in the last step.

8. The plasma processing apparatus of claim 1, wherein the plasma measuring unit determines a value of a specific spectrum included in the plasma as the spectroscopically measured value.

9. The plasma processing apparatus of claim 1, wherein the plasma measuring unit determines a ratio of a first spectrum and a second spectrum included in the plasma as the spectroscopically measured value.

10. The plasma processing apparatus of claim 1, wherein the plasma measuring unit determines an integral value of the entire spectra within a certain range of wavelengths included in the plasma as the spectroscopically measured value.

11. A plasma processing apparatus in which a plasma processing for a substrate to be processed is divided into a plurality of steps and process conditions are independently set for each step, the apparatus comprising:
an evacuable processing container configured to removably accommodate the substrate;
a process condition setting unit configured to set process conditions for performing a plasma processing on one substrate to be processed;
a plasma generating unit configured to generate plasma of a processing gas in the processing container in accordance with the process conditions;
a target value setting unit configured to set a target value on a determined process result;
a plasma measuring unit configured to spectroscopically measure atomic emission of the plasma generated in the processing container and calculate a spectroscopically measured value in a predetermined interval of time;
a process result predicting unit configured to predict a value of the process result from the spectroscopically measured value obtained from the plasma measuring unit in a predetermined interval of time; and
a process control unit configured to adjust at least one of the process conditions in a corresponding step as a process parameter, based on the target value of the process result given from the target value setting unit and the predicted value of the process result for each step given from the process estimating unit in a predetermined interval of time.

12. A plasma processing method in which a plasma processing for a substrate to be processed is divided into a plurality of steps and process conditions are independently set for each step, the method comprising:
setting a target value for each step on a determined process result;
generating plasma of a processing gas in an evacuable processing container configured to removably accommodate the substrate;
spectroscopically measuring atomic emission of the plasma generated in the processing container to determine a spectroscopically measured value;
estimating a value of the process result in a corresponding step from the spectroscopically measured value after the completion of each step; and
adjusting at least one of the process conditions as a process parameter in a next step of each step, based on the target value of the process result for the next step and the estimated value of the process result for each step.
